(19) United States
(12) Patent Application Publication
(10) Pub. No.: US 2005/0062106 A1
(43) Pub. Date: Mar. 24, 2005

(54) Luminance adjusting display apparatus

(76) Inventors: Yukihiro Noguchi, Motosu-gun (JP); Akifumi Sasaki, Oogaki (JP); Junka Kaya, Niwa-gun (JP)

Correspondence Address: MCDERMOTT WILL & EMERY LLP, 600 13TH STREET, N.W., WASHINGTON, DC, 20005-3096, US

(21) Appl. No.: 10/935,719

(22) Filed: Sep. 8, 2004

(30) Foreign Application Priority Data
Sep. 8, 2003 (JP) 2003-315538

(51) Int. Cl. H01L 21/00

(52) U.S. Cl. 257/347

(57) ABSTRACT

Semiconductor film forming positions are positions where positioned are a plurality of same conductive-type transistors that control luminance of optical elements in a drive circuit of each pixel. The semiconductor film forming positions in a semiconductor film forming process are arranged in such positions that they receive heat treatment of the same level of intensities in an intensity distribution. The semiconductor film forming positions are arranged in the same shot region in a heat treatment such as excimer laser annealing, and is arranged within a range corresponding to superposition width in a superimposed irradiation. Thereby, the uniformity of characteristics is achieved for the plurality of transistors formed in the semiconductor film forming positions.

### BACKGROUND OF THE INVENTION

1. Field of the Invention

The present invention relates to display apparatuses, and it particularly relates to improving the luminance characteristics of active matrix type display apparatuses.

2. Description of the Related Art

Much attention is being directed to flat light-emitting type organic thin film EL displays as a device using organic thin film EL elements. Displays of this type are characterized by a matrix drive system of unit pixels, each composed of an organic thin film EL element structure, which are disposed two-dimensionally on the surface plane of a single supporting substrate.

As elements for this matrix drive system, low-temperature polycrystalline silicon TFTs are used because they can incorporate a peripheral drive circuit, can reduce the element size of a pixel circuit, and can use an inexpensive material for the supporting substrate.

In forming a polycrystalline silicon layer used in low-temperature polycrystalline silicon TFTs, the mainstream method is an ELA (excimer laser annealing) process, in which an amorphous silicon is annealed by the irradiation of excimer laser. In the conventional method of such laser annealing, superimposed irradiation is carried out at a scanning pitch whereby a substrate or a laser beam is scanned by irradiating a pulse line beam of excimer laser.

The line laser beam, however, has such disadvantages as irradiation intensity distribution and inter-shot errors. Japanese Patent Application Laid-Open No. Hei09-321310 (Reference (1)) and Japanese Patent Application Laid-Open No. Hei11-330000 (Reference (2)) disclose a technique of 45-degree scanning of laser beam to solve the problem of non-uniformity of the elements due to irradiation intensity distribution or inter-shot errors. Japanese Patent Application Laid-Open No. Hei11-345783 (Reference (3)) discloses a double scanning technique for the same purpose.

On the other hand, flat light-emitting type organic thin film EL displays, when designed with the basic 2-TFT scheme for their pixel drive circuit, sometimes present the problem of uneven luminance due to variations in TFT characteristics such as threshold voltage or mobility. To solve this problem, a variety of pixel circuits have been proposed. For example, Japanese Patent Application Laid-Open No. 2001-147659 (Reference (4)) discloses a current-mirror type current-specifying method, and “A New AMOLED Pixel Design by Self-compensating Threshold Voltage Variation of Poly-Si TFT” (Reference (5)) discloses a voltage programming circuit. In these circuits, it is requisite that a plurality of same conductive-type transistors for determining the drive current of EL elements or for compensating the element characteristics of the pixel drive circuit have identical characteristics.

Yet, while the above-described methods for improving the irradiation intensity distribution of excimer laser or reducing the inter-shot errors can improve the overall uniformity, it is very difficult for them to achieve the uniformity of characteristics for the transistors within a pixel.

Furthermore, such complex circuit structures as disclosed in the above References (1) to (5) require use of a larger number of elements for the pixel drive circuit, which produces the problem of a lowered aperture ratio.

Related Art List

(1) Japanese Patent Application Laid-Open No. Hei09-321310 (page 4, FIG. 1)
(2) Japanese Patent Application Laid-Open No. Hei11-330000 (page 3, FIG. 1)
(3) Japanese Patent Application Laid-Open No. Hei11-345783 (page 3, FIG. 1)
(4) Japanese Patent Application Laid-Open No. 2001-147659 (pages 7-9, FIG. 1)
(5) “A New AMOLED Pixel Design by Self-compensating Threshold Voltage Variation of Poly-Si TFT” (By Sang-Hoon Jung et al., AM-LCD 02, 2002 INTERNATIONAL WORKSHOP ON ACTIVE-MATRIX LIQUID-CRYSTAL DISPLAYS, THE JAPAN SOCIETY OF APPLIED PHYSICS, Jul. 10-12, 2002, pp. 13-16)

### SUMMARY OF THE INVENTION

The present invention has been made in view of the foregoing circumstances, and an object thereof is to provide a technology by which to reduce the unevenness of luminance by achieving uniformity for specific transistor characteristics within a pixel. Another object thereof is to present a technology for raising the aperture ratio for a pixel drive circuit with a larger number of elements.

A preferred embodiment of the present invention relates to a display apparatus. This display apparatus is characterized by a structure that semiconductor films of a plurality of same conductive-type transistors which control luminance of optical elements in a pixel area are arranged in such positions that the semiconductor films in a semiconductor film forming process receive heat treatment of substantially the same level of intensities in an intensity distribution of heat treatment.

In the present invention, a plurality of same conductive-type transistors which control the luminance are, for instance, the transistors which determine the amount of current to drive light-emitting elements or those that compensate the element characteristics of a pixel driving circuit. The plurality of same conductive-type transistors are typically turn-off transistors for turning light off and turn-on transistors for turning light on in duty control.

The present invention takes into account that the intensity distribution of heat treatment varies in places and it often varies depending on position. And in the present invention the attention is focused on the distribution of heat treatment intensities, and a plurality of same conductive-type transistors that control the luminance are arranged in a position (hereinafter referred to as “identical heat-treatment intensity position” as appropriate) where the same level of intensity of heat treatment is applied. As a result, the high-level uniformity of characteristics for the transistors can be achieved, and the unevenness in luminance can be reduced.

The plurality of same conductive-type transistors may be arranged side by side in a scanning direction of the heat treatment. Thereby, the non-uniformity, of the transistor characteristics, caused by the distribution of heat treatment intensities in the longitudinal direction of a heat treatment region (generally perpendicular to the scanning direction) can be reduced.

Another preferred embodiment of the present invention relates also to a display apparatus. This display apparatus is characterized by a structure such that semiconductor films of a plurality of same conductive-type transistors which control luminance of optical elements in a pixel area are arranged in an identical shot region of heat treatment in a semiconductor film forming process. The present embodiment is preferably applied to a display apparatus of a type in which the heat treatment is done in such a manner that a shot is repeated while changing the position of a shot. According to this preferred embodiment, the non-uniformity, of characteristics for the transistors, caused by the inter-shot error can be reduced, and the unevenness in luminance can be reduced. Preferably, the plurality of transistors are disposed in the above-mentioned identical heat-treatment intensity position, in which the intensity distribution of heat treatment-is taken into account, and in the identical shot region. Thereby, the unevenness in luminance can be further reduced.

The plurality of same conductive-type transistors may be disposed within a range corresponding to superposition width in a superimposed irradiation of the heat treatment. Thereby, the non-uniformity of characteristics for the transistors due to the inter-shot error can be further reduced.

The plurality of same conductive-type transistors may be disposed in close proximity thereto. The plurality of transistors are arranged in further close proximity thereto in the identical heat-treatment intensity position and are also arranged in further close proximity thereto in the identical shot region. As a result, the non-uniformity of characteristics for the transistors due to the variation in the semiconductor film thickness can be reduced and the unevenness in luminance-can be further reduced.

The plurality of same conductive-type transistors may be disposed within an identical dose region based on a layout in an impurity dose processing. As a result, the unnecessary space in a pixel can be eliminated, the unevenness in luminance is reduced, and the aperture ratio can be improved. Although the plurality of same conductive-type transistors may typically include the above-described transistors for controlling luminance, they are not limited to those transistors only and more on this matter will be explained later in the section of DETAILED DESCRIPTION OF THE INVENTION.

It is to be noted that any arbitrary combination or recombination of the above-described structural components and expressions changed to a method, a system and so forth are all effective as the present embodiments and is encompassed by the scope of claims.

Moreover, this summary of the invention does not necessarily describe all necessary features so that the invention may also be sub-combination of these described features.

### BRIEF DESCRIPTION OF THE DRAWINGS

FIG. 1 illustrates an example of a circuit structure for one pixel of a display apparatus to which the present invention is preferably applied.

FIG. 2 is a time chart showing an operation of a display apparatus shown in FIG. 1.

FIG. 3 illustrates an arrangement of semiconductor film forming positions according to an embodiment of the present invention.

FIG. 4 illustrates an arrangement of semiconductor film forming positions according to another embodiment of the present invention.

FIG. 5 illustrates an arrangement of semiconductor film forming positions according to still another embodiment of the present invention.

FIG. 6 illustrates an arrangement of semiconductor film forming positions according to still another embodiment of the present invention.

FIG. 7 illustrates a pattern of a pixel circuit according to an exemplary embodiment of the present invention.

FIG. 8 illustrates another example of a circuit structure for one pixel of a display apparatus to which the present invention is preferably applied.

FIG. 9 illustrates a pattern of a pixel circuit according to another exemplary embodiment of the present invention.

### DETAILED DESCRIPTION OF THE INVENTION

The invention will now be described based on preferred embodiments, which do not intend to limit the scope of the present invention but exemplify the invention, together with drawings. All of the features and the combinations thereof described in the embodiments are not necessarily essential to the invention.

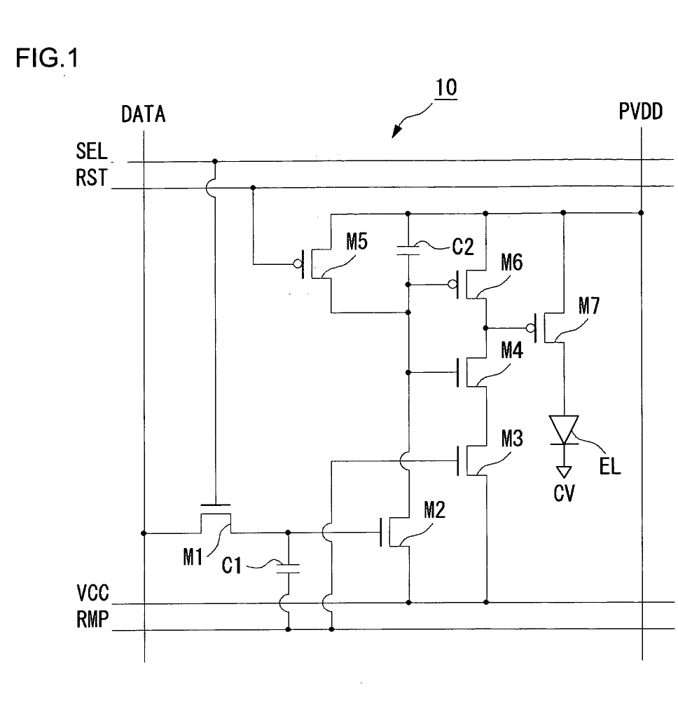

FIG. 1 illustrates an example of a circuit structure for one pixel of a display apparatus according to a preferred embodiment of the present invention. As is illustrated in FIG. 1, this pixel circuit 10 includes a light-emitting element EL and its drive circuit. And the drive circuit, as is shown from below to the left to above to the right of FIG. 1, is comprised of a data setting transistor M1 and a capacitor Cl related thereto, a turn-off transistor M2 for turning light off, a turn-on transistor M3 for turning light on, an initialize transistor M5 and a capacitor C2 related thereto, a first auxiliary transistor M4 and a second auxiliary transistor M6, and a drive transistor M7.

Of these constituent elements, a gate electrode of the initialize transistor M5 is connected to a reset signal line RST, a source electrode thereof to a first power supply line PVDD, and a drain electrode thereof to gate electrodes of the first auxiliary transistor M4 and the second auxiliary transistor M6. The capacitor C2 has a function of fixing the potential at the gate electrodes of the first auxiliary transistor M4 and the second auxiliary transistor M6 after a reset.

The first auxiliary transistor M4 and the second auxiliary transistor M6 constitute an inverter, wherein a source electrode of the second auxiliary transistor M6 is connected to the first power supply line PVDD and a source electrode of the first auxiliary transistor M4 is connected to a second power supply line VCC via the turn-on transistor M3. The potential of the first power supply line PVDD is higher than the potential of the second power supply line VCC. And drain electrodes of the first auxiliary transistor M4 and the second auxiliary transistor M6 are connected to a gate electrode of the drive transistor M7.

The drive transistor M7 is a transistor that has the light-emitting element EL emit light by supplying power thereto, of which a source electrode is connected to the first power supply line PVDD and a drain electrode to the light-emitting element EL.

The turn-on transistor M3 and the turn-off transistor M2 are provided to turn on and turn off the light of the light-emitting element EL, respectively. Source electrodes of the turn-on transistor M3 and the turn-off transistor M2 are connected to the second power supply line VCC, a drain electrode of the turn-on transistor M3 is connected to the source electrode of the first auxiliary transistor M4, and a drain electrode of the turn-off transistor M2 is connected to the gate electrodes of the first auxiliary transistor M4 and the second auxiliary transistor M6.

Next, a structure for performing duty control of the luminance of a light-emitting element EL will be explained. As shown in FIG. 1, a gate electrode of the turn-on transistor M3 is connected to a ramp signal line RMP. A gate electrode of the turn-off transistor M2 is connected to a drain electrode of the data setting transistor M1. And a source electrode of the data setting transistor M1 is connected to a data line DATA, and a gate electrode of the data setting transistor M1 is connected to a scanning line SEL. A capacitor C1 for holding voltage is provided between the gate electrode of the turn-off transistor M2 and the ramp signal line RMP.

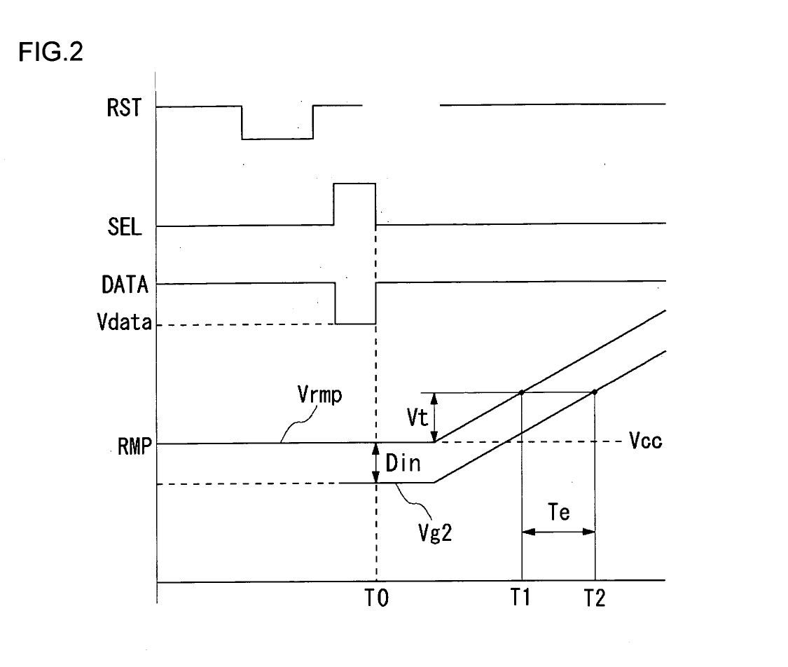

FIG. 2 is a time chart showing the operation of a display apparatus as illustrated in FIG. 1. Referring to FIG. 1 and FIG. 2, the operation of the above-described display apparatus will now be described.

For a frame operation, a reset signal of the reset signal line RST goes low. As a result, the initialize transistor M5 turns on, and the gate electrodes of the first and second auxiliary transistors M4 and M6 are set to potential of the first power supply line PVDD. This turns on the first auxiliary transistor M4 and turns off the second auxiliary transistor M6.

Then a scanning signal of the scanning line SEL goes high. When the scanning signal goes high, the data setting transistor M1 turns on, so that drain potential of the data setting transistor becomes nearly equal to source potential thereof. That is, gate potential Vg2 of the turn-off transistor M2 becomes nearly equal to potential of the data line DATA.

Now, during a period when the scanning signal of the scanning line SEL is in the high level, potential of the data line DATA is set to Vdata. Suppose that the difference between the potential Vdata of the data line DATA and the potential Vrmp of the ramp signal line RMP is denoted by Din, then Din will be given as Din=Vrmp−Vdata. The capacitor C1 is charged by the voltage Din. When the scanning signal of the scanning line SEL goes low at time T0, the data setting transistor M1 turns off. As a result, the voltage applied to the capacitor C1 is fixed by the voltage Din at time T0.

Now the potential Vrmp of the ramp signal line RMP begins increasing. At time T1 when a potential difference between the ramp signal line RMP and the second power supply line VCC, namely, gate-source voltage of the turn-on transistor M3, reaches a threshold voltage Vt of the turn-on transistor M3, the turn-on transistor M3 is turned on. Then the gate potential of the drive transistor M7 becomes low and turns on, and then the light-emitting element EL emits light.

FIG. 2 also shows the gate potential Vg2 of the turn-off transistor M2 together with a ramp signal. Although the gate potential Vg2 of the turn-off transistor M2 is lower than potential Vrmp of the ramp signal line RMP by a voltage applied to the capacitor C1, the voltage applied to this capacitor C1 is the voltage value Din set at T0. Hence, the gate potential Vg2 of the turn-off transistor M2 increases with the potential Din of the ramp signal while maintaining a state of being lower than the potential Vrmp, namely, the gate potential of the turn-off transistor by the voltage Vdata. As shown in FIG. 2, at time T2 a gate-source voltage of the turn-off transistor M2 reaches the threshold voltage Vt later than the turn-on transistor M3. As a result, the turn-off transistor M2 turns on, the first auxiliary transistor M4 turns off, and the second auxiliary transistor M6 turns on. Upon this, the gate potential of the drive transistor M7 gets closer to the potential of the first power supply line PVDD, so that the drive transistor M7 turns off and the light-emitting element EL turns off.

In the above-described light-emitting operation for one frame, the emission time Te, or T2−T1, is a period of time from when the turn-on transistor M3 turns on to when the turn-off transistor M2 turns off. This emission time Te changes in accordance with a potential difference between the gate potential of the turn-on transistor M3 and the gate potential Vg2 of the turn-off transistor M2, namely, the voltage Vdata of the capacitor at time T0, so that the potential given to the data line DATA determines a duty ratio. In this manner, the duty control of a display apparatus as illustrated in FIG. 1 is accomplished.

Preferred embodiments according to the present invention will be described hereinafter in the light of the above examples.

In the example of FIG. 2, the ramp signal RMP corresponds to the gate-source voltage of the turn-on transistor M3, and the gate potential Vg2 of the turn-off transistor M2 corresponds to the gate-source voltage of the same transistor. Hence, in the control as illustration FIG. 2, the luminance is controlled on condition that the turn-on transistor M3 and the turn-off transistor M2 have the same threshold voltage Vt, namely, the same characteristics. In other words, any disagreement in characteristics between the turn-on transistor M3 and the turn-off transistor M2 can cause errors of emission time Te in the luminance control of FIG. 2, which in turn cause unevenness in luminance. Therefore, the unevenness in luminance can be effectively reduced by ensuring the uniformity of characteristics between the turn-on transistor M3 and the turn-off transistor M2.

The above-described turn-on transistor M3 and turn-off transistor M2 are examples of a plurality of same conductive-type transistors that are used to control the luminance in the present invention. As will be described hereinbelow, the present invention provides a technology for achieving uniform characteristics for the plurality of same conductive-type transistors within a pixel.

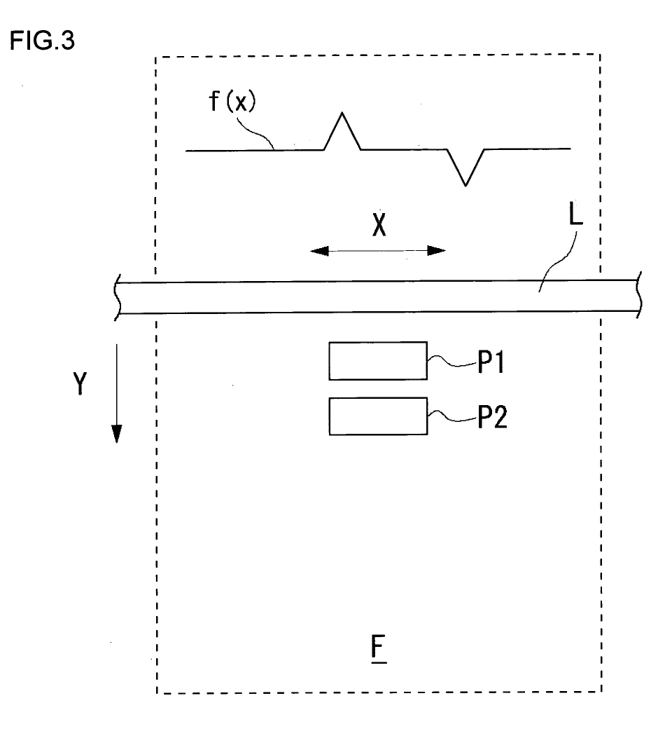

FIG. 3 illustrates a first embodiment according to the present invention. FIG. 3 illustrates an amorphous silicon film F in a pixel region when a semiconductor film of transistors is being formed.

In forming semiconductor films, a heat treatment is carried out to the amorphous silicon film F. The heat treatment according to embodiments of the present invention is ELA (excimer laser annealing) In ELA, a long and narrow excimer laser beam L as shown in FIG. 3 is scanned in the scanning direction Y, which is perpendicular to the longitudinal direction X of the excimer laser beam L.

Here two same conductive-type transistors are assumed. The present embodiment is characterized by a feature that semiconductor film forming positions P1 and P2 for these transistors are arranged side by side in the scanning direction Y. As a result, the semiconductor film forming positions P1 and P2 are placed in an identical position in the longitudinal direction X of the beam. That is, the pattern setting is done in a manner such that the polycrystalline silicon region is subjected to the beam irradiation in an identical region in the longitudinal direction X of the beam. The reason for this pattern arrangement is as follows.

As shown at the top of FIG. 3, an excimer laser beam L has an intensity distribution f(x) in the longitudinal direction X of the beam. And this intensity distribution remains the same throughout the scanning process. Therefore, if they are arranged in the scanning direction Y, that is, in an identical position in the longitudinal direction X of the beam, the semiconductor film forming positions P1 and P2 will be subjected to a beam irradiation of the same intensity.

According to the present embodiment, therefore, the semiconductor film forming positions P1 and P2 in the semiconductor film forming process are arranged in such positions that they receive heat treatment of the same level of intensities in the intensity distribution. Thus uniformity of characteristics can be achieved for the transistors formed in the semiconductor film forming positions P1 and P2. More specifically, according to the present embodiment, which focuses its attention on the presence of distribution of different heat treatment intensities within a pixel, a higher level of uniformity in characteristics for the transistors is achieved by arranging a plurality of same conductive-type transistors in positions where they are subject to the same level of intensities of heat treatment.

In particular, the present invention, which is characterized by the arrangement of the semiconductor film forming positions of a plurality of transistors in the scanning direction of heat treatment, can reduce unevenness in transistor characteristics that would otherwise be caused by the distribution of heat treatment intensities in the longitudinal direction of a heat treatment region (generally perpendicular to the scanning direction).

In the example of FIG. 3, the semiconductor film forming positions P1 and P2 are completely identical in the longitudinal direction of the beam. That is, the semiconductor film forming positions P1 and P2 have exactly the same X coordinates. The present invention, however, is not limited to this arrangement. The semiconductor film forming positions P1 and P2 may not be aligned in their X coordinates so long as they are practically within a range of the same beam intensity. For example, the positions P1 and P2 may be only partially identical.

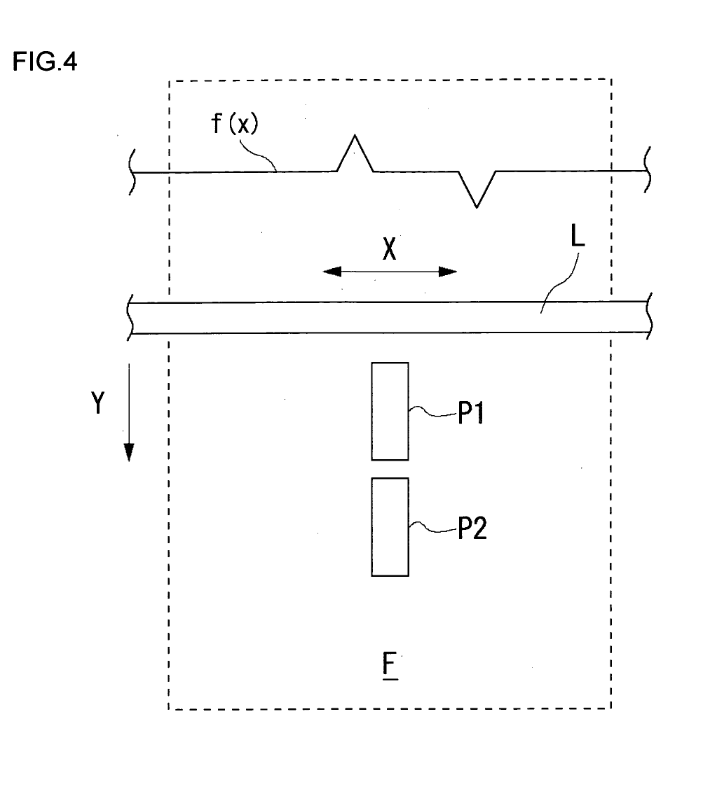

FIG. 4 illustrates another embodiment according to the present invention. According to the embodiment illustrated in FIG. 3, the semiconductor film forming positions P1 and P2 are arranged in a manner such that the long sides of the semiconductor films for the transistors are in parallel with the longitudinal direction X of the beam. In contrast to this, this embodiment as illustrated in FIG. 4 is such that the semiconductor film forming positions P1 and P2 are so arranged that the long sides of the semiconductor films for the transistors are perpendicular to the longitudinal direction X of the beam.

In this embodiment as illustrated in FIG. 4, too, the semiconductor film forming positions P1 and P2 are arranged side by side in the scanning direction Y of the excimer laser beam L in positions where they are subject to the same level of intensities in the heat treatment distribution. Hence, this embodiment also provides the same advantages of the above-described embodiment in the present invention.

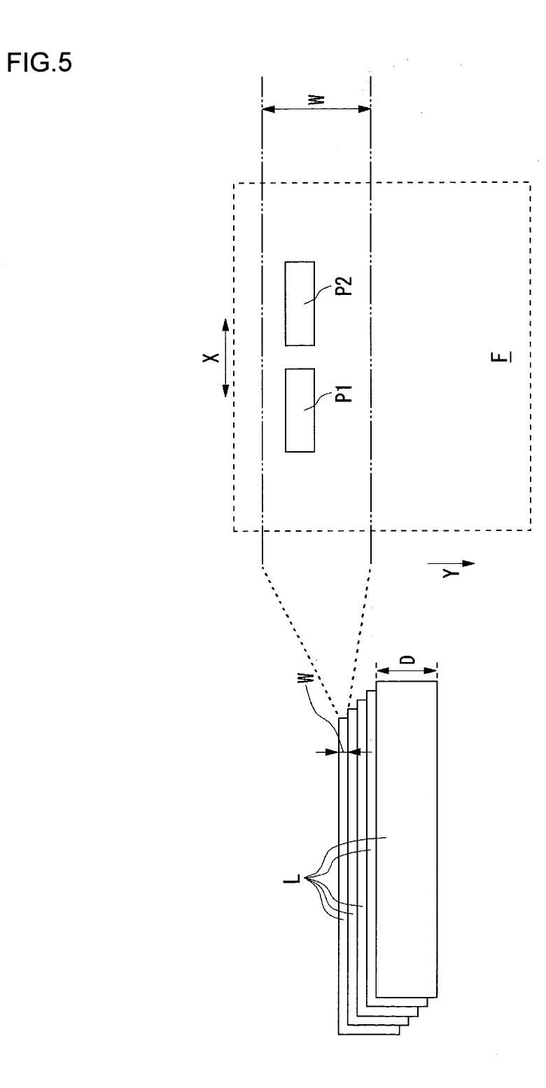

FIG. 5 illustrates still another embodiment according to the present invention. In this embodiment, the semiconductor film forming positions P1 and P2 are arranged in an identical inter-shot region of the excimer laser beam. In particular, as will be described below, they are arranged in a range corresponding to superposition width W in the superimposed irradiation of the excimer laser beam L.

Suppose, for example, that beam width D of excimer laser beam L is 300 micrometers and the irradiation is performed ten times as the superimposed irradiation. In this case, the irradiation position of the excimer laser beam L is shifted or staggered by 30 micrometers at each time of the irradiation.

In this embodiment, the semiconductor film forming positions P1 and P2 are disposed within a range corresponding to the superposition width W. In the example of FIG. 5, the semiconductor film forming positions P1 and P2 are arranged in such a manner that P1 and P2 forms a side-by-side area parallel to and equidistant from a longitudinal direction of laser beam. Thus, the semiconductor film forming positions P1 and P2 receive the irradiation of the only excimer laser beam L of the same shot.

According to the present embodiment as described above, the semiconductor film forming positions P1 and P2 are disposed in the same shot area of heat treatment in a semiconductor film process. Thus, the non-uniformity of characteristics for the transistors due to the inter-shot error can be reduced.

Moreover, according to the present embodiment, the semiconductor film forming positions P1 and P2 are disposed within a range that corresponds to the superposition width in the superimposed irradiation of the heat treatment, so that the irradiation of the same shot only is performed on the semiconductor film forming positions P1 and P2. Thus, the non-uniformity of characteristics for the transistors due to the inter-shot error can be further reduced.

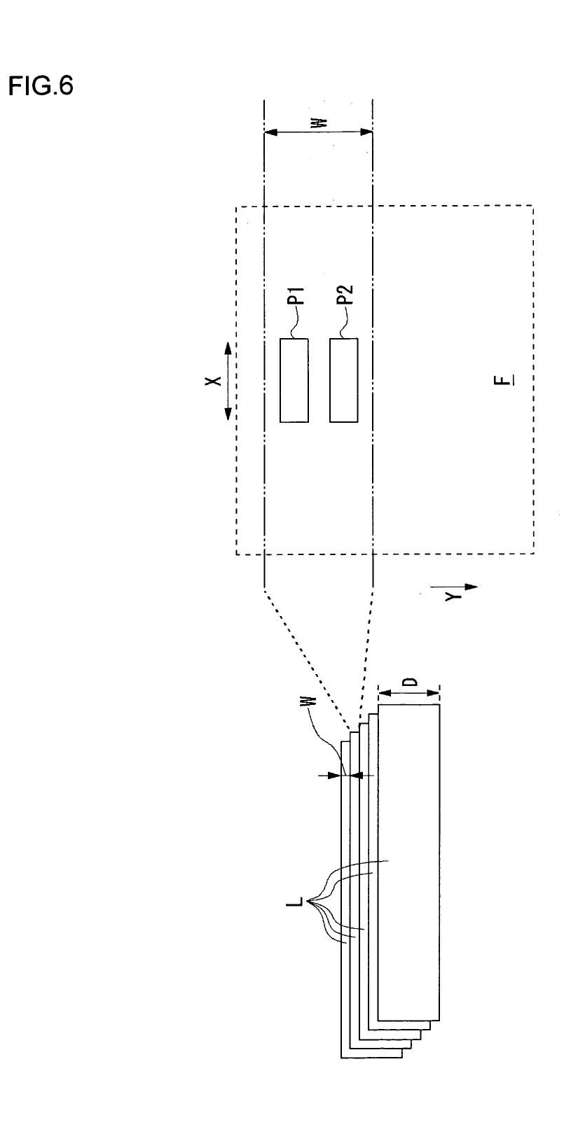

FIG. 6 illustrates still another embodiment according to the present invention. In this embodiment, the structure of FIG. 3 is combined with that of FIG. 5. That is, the semiconductor film forming positions P1 and P2 are arranged side by side in the scanning direction Y, and are disposed in the same shot region. Moreover, even in the same shot region, P1 and P2 are also disposed within a range of the superposition width in the superimposed irradiation. In the example of FIG. 6, the semiconductor film forming positions P1 and P2 are arranged in such a manner that P1 and P2 are parallel to the longitudinal direction of laser beam and lie within the superimposed width of beam in the same region.

According to the present embodiment, the variation in characteristics caused by the heat treatment intensity distribution is reduced and the variation in characteristics caused by the inter-shot variation is reduced. Thus, the increasing uniformity of characteristics for the transistors can be achieved.

Next, still another embodiment according to the present invention will be described. According to this embodiment, the semiconductor film forming positions P1 and P2 are disposed in further close proximity in the structures as shown in FIG. 3 to FIG. 6. More specifically, distances among a plurality of polycrystalline silicon film patterns that correspond to the semiconductor film forming positions P1 and P2 are very closely located to each other and are set to the minimum size to the degree that the elements of such the minimum size can be formed.

According to the present embodiment, the non-uniformity of characteristics for the transistors due to variations in the film thickness of the semiconductor can be reduced. Thus, the increasing uniformity of characteristics for the transistors can be achieved.

Next, still another embodiment according to the present invention will be described. According to this embodiment, a plurality of same conductive-type transistors are arranged within an identical dose region based on a layout in an impurity dose processing. More specifically, a structure is adopted such that in one pixel a dose mask region of impurities is formed in one mask region.

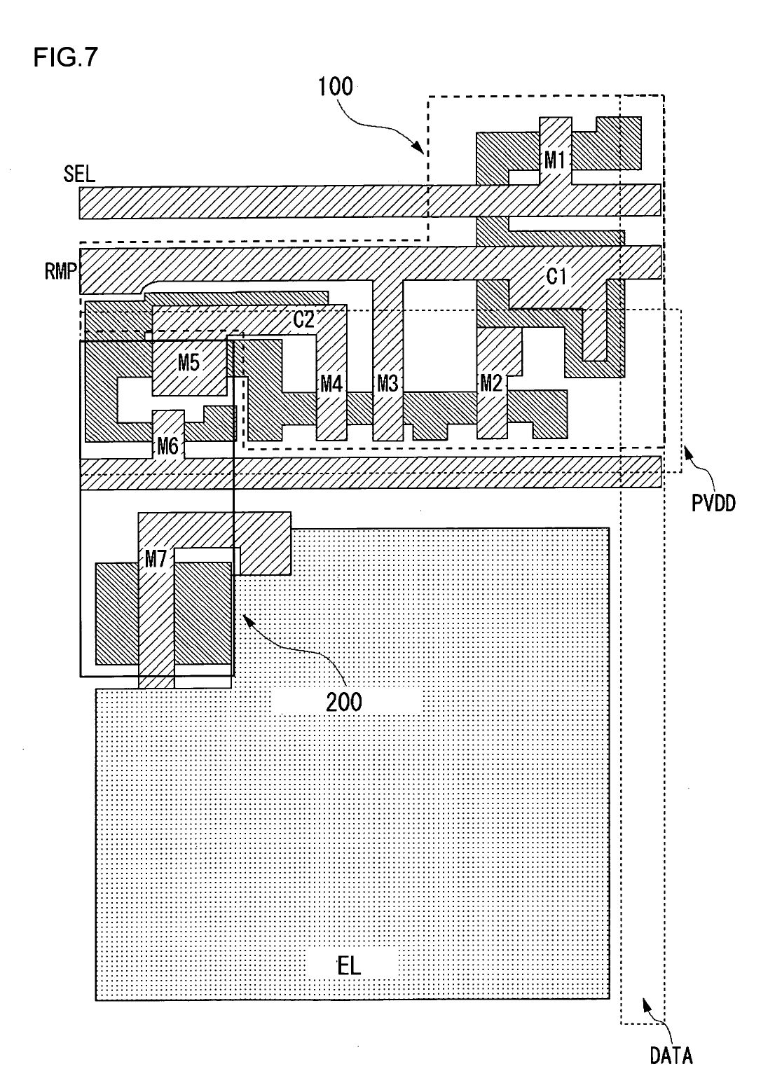

FIG. 7 illustrates an exemplary embodiment. The structure of FIG. 7 corresponds to the pixel circuit of FIG. 1. That is, transistors M1 to M7, capacitors C1 and C2 and light-emitting element EL shown in FIG. 7 correspond to the respective components of the same reference numerals and symbols used in FIG. 1.

According to the present embodiment as shown in FIG. 7, the turn-on transistor M3 and the turn-off transistor M2 are arranged in close proximity to each other, and the both transistors M3 and M2 are disposed in an N+ doping area 100. The same conductive-type transistors such as data setting transistor M1 and first auxiliary transistor M4 are also disposed in the same N+ doping area 100. The transistors M5, M6 and M7 of an identical conductive type having the opposite channel are disposed in a P+ doping area 200.

According to the present embodiments as described above, since a plurality of same conductive-type transistors are arranged within an identical dose region based on a layout in an impurity dose processing, unnecessary space in a pixel can be eliminated and the aperture ratio can be improved. In this connection, as described above, a plurality of same conductive-type transistors may not be limited to the turn-on and turn-off transistors for controlling the luminance.

Moreover, according to the present embodiments, it is preferable that the transistors are disposed in close proximity thereto and are arranged within an identical dose region based on an impurity-dose layout as described above. As a result, further significantly advantageous aspects of the present invention are obtained.

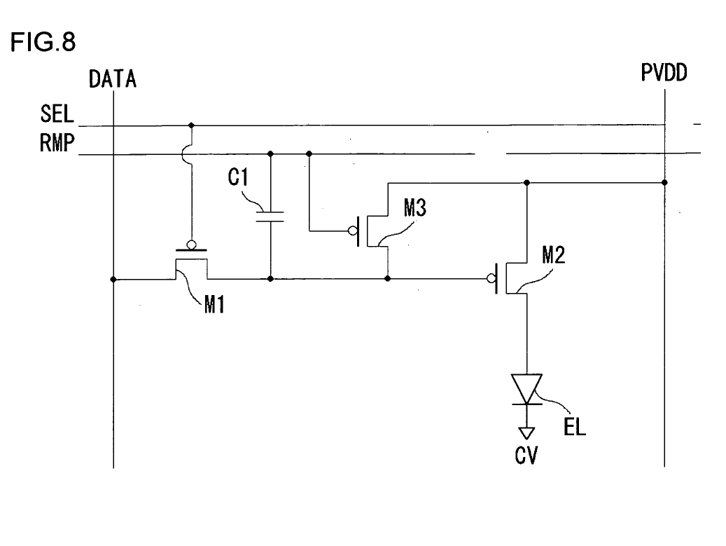

FIG. 8 illustrates another example of a circuit structure for one pixel of a display apparatus to which the present invention is preferably applied. Referring to FIG. 8, a pixel circuit includes transistors M1, M2 and M3 as components of a pixel driving circuit. Of these transistors, the transistor M1 is used for data setting. The transistor M2 is used to turn light off and the transistor M3 is used to turn light on. Similar to the pixel circuit shown FIG. 1, the emission time Te is controlled by the transistors M2 and M3 so as to perform the duty control.

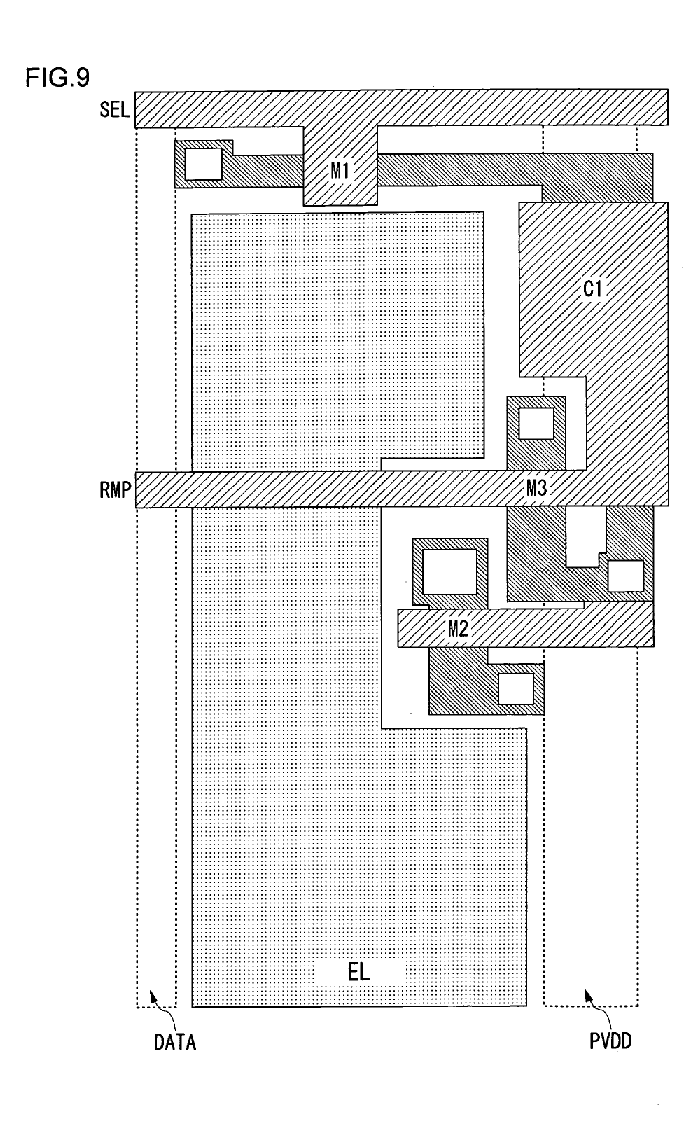

In the example of FIG. 8, the arrangements implemented as in FIG. 3 to FIG. 6 are preferably adopted for the transistors M2 and M3 so as to achieve the uniformity of characteristics for the transistors. The transistors M2 and M3 are preferably disposed in close proximity to each other. FIG. 9 illustrates a pattern of a pixel circuit corresponding to the pixel circuit shown in FIG. 8. It is preferable that the arrangement of the transistors M1, M2 and M3 be suitably set, on the pattern shown in FIG. 9, based on the layout in an impurity dose processing.

The present invention has been described based on a variety of preferred embodiments. According to the present embodiments as described above, the uniformity of characteristics for a plurality of transistors that control the luminance data can be achieved, thereby reducing the unevenness in luminance.

The turn-on transistor M3 and the turn-off transistor M2 as in FIG. 1 may be used to determine the drive current of a light-emitting element. Thus, according to the present embodiments, the uniformity of characteristics for a plurality of same conductive-type transistors that determine the drive current of light-emitting elements can be achieved, so that the unevenness in luminance can be reduced.

In terms of the fact that the luminance is accurately controlled even if the characteristics of the turn-on transistor M3 and the turn-off transistor M2 as shown in FIG. 1 are both shifted in the same way (note that the emission time Te remains the same even if the emission timings differ), it may be inferred that the turn-on transistor M3 and the turn-off transistor M2 as shown in FIG. 1 compensate the characteristics of elements. Thus, according to the present embodiments, the uniformity of characteristics for a plurality of same conductive-type transistors that compensate the element characteristics of a pixel driving circuit can be achieved, so that the unevenness in luminance can be reduced.

As described above, the turn-on transistor M3 and the turn-off transistor M2 may be used to perform the duty control on the luminance of light-emitting elements. Thus, according to the present embodiments, the uniformity of characteristics for the turn-on transistors and turn-off transistors in the duty control can be achieved, so that the unevenness in luminance can be reduced.

The present invention has been described based on the embodiments which are only exemplary and is thus not limited thereto. It is understood that there exist other various modifications to the combination of each component and process described above and that such modifications are encompassed by the scope of the present invention which is defined by the appended claims. For example, the heat treatment is not limited to ELA and any other heat treatment may be used as long as it is such that a light source or a substrate is moved while being irradiated with energy waves of any sort. For example, laser annealing using YAG laser or argon laser may be used. Lamp annealing or rapid thermal annealing may also be used.

The present invention may be applied to and is useful in a field of any display apparatus such as active matrix type display apparatus.

1. A display apparatus characterized in that semiconductor films of a plurality of same conductive-type transistors which control luminance of optical elements in a pixel area are arranged in such positions that the semiconductor film forming positions in a semiconductor film forming process receive heat treatment of substantially the same level of intensities in an intensity distribution of the heat treatment.

2. A display apparatus according to claim 1, wherein the plurality of same conductive-type transistors are turn-off transistors for turning light off and turn-on transistors for turning light on in duty control.

3. A display apparatus according to claim 1, wherein the plurality of same conductive-type transistors are arranged side by side in a scanning direction of the heat treatment.

4. A display apparatus according to claim 1, wherein the plurality of same conductive-type transistors are arranged in an identical shot region of the heat treatment.

5. A display apparatus according to claim 1, wherein the plurality of same conductive-type transistors are disposed in close proximity thereto.

6. A display apparatus according to claim 1, wherein the plurality of same conductive-type transistors are disposed within an identical dose region based on a layout in an impurity dose processing.

7. A display apparatus characterized in that semiconductor films of a plurality of same conductive-type transistors which control luminance of optical elements in a pixel area are arranged in an identical shot region of heat treatment in a semiconductor film forming process.

8. A display apparatus according to claim 7, wherein the plurality of same conductive-type transistors are disposed within a range corresponding to superposition width in a superimposed irradiation of the heat treatment.

9. A display apparatus according to claim 7, wherein the plurality of same conductive-type transistors are disposed in close proximity thereto.

10. A display apparatus according to claim 7, wherein the plurality of same conductive-type transistors are disposed within an identical dose region based on a layout in an impurity dose processing.
